(19) United States
(12) Patent Application Publication
(10) Pub. No.: US 2025/0145781 A1
(43) Pub. Date: May 8, 2025

(54) FLUORORESIN FILM, METAL-CLAD LAMINATE AND SUBSTRATE FOR CIRCUIT

(71) Applicant: DAIKIN INDUSTRIES, LTD., Osaka (JP)

(72) Inventors: Masahiko KAWAMURA, Osaka-shi (JP); Tatsuya HIGUCHI, Osaka-shi (JP); Kenzo TAKAHASHI, Osaka-shi (JP); Hirokazu KOMORI, Osaka-shi (JP); Hideaki TENKAJI, Osaka-shi (JP); Junpei TERADA, Osaka-shi (JP); Nobuyuki KOMATSU, Osaka-shi (JP)

(73) Assignee: DAIKIN INDUSTRIES, LTD., Osaka (JP)

(21) Appl. No.: 19/018,051

(22) Filed: Jan. 13, 2025

Related U.S. Application Data
(63) Continuation of application No. PCT/JP2023/026942, filed on Jul. 24, 2023.

(30) Foreign Application Priority Data
Jul. 22, 2022 (JP) 2022-117315

(51) Int. Cl. C08J 5/18; B32B 15/082

(52) U.S. Cl. CPC C08J 5/18; B32B 15/082; B32B 2327/18; B32B 2457/08; C08J 2327/18; C08J 2327/20

(57) ABSTRACT

Provided is a fluororesin film with high uniformity in adhesion strength of the film. A fluororesin film that is a film comprising a fluororesin-containing composition, wherein at least one surface of the fluororesin film has an average value of contact angles for water measured at 5 points with intervals of 100 mm in a travel direction of 105° or less and an average value of contact angles for n-hexadecane measured at 5 points with intervals of 100 mm in the travel direction of 45° or less at locations of center and 100 mm from respective left and right ends.

### CROSS REFERENCE TO RELATED APPLICATIONS

This application is a Rule 53 (b) Continuation of International Application No. PCT/JP2023/026942 filed Jul. 24, 2023, claiming priority based on Japanese Patent Application No. 2022-117315 filed Jul. 22, 2022, the respective disclosures of which are incorporated herein by reference in their entirety.

### TECHNICAL FIELD

The present disclosure relates to a fluororesin film, a metal-clad laminate and a substrate for circuits.

### BACKGROUND ART

Epoxy resin and polyimide resin have been widely used for circuit boards as an insulation layer. In recent years, for high frequency circuit boards used for applications in a high frequency region of a few tens of GHz, structures in which an insulation layer made of fluororesin is formed on metal foil have been proposed in consideration of dielectric properties and hygroscopic properties.

For such printed wiring boards, fluororesin film has been surface-treated to provide adhesiveness to metal foil.

### CITATION LIST

### Patent Literature

Patent Literature 1: Japanese Patent Laid-Open No. 2019-11413

Patent Literature 2: Japanese Patent Laid-Open No. 2008-200991

Patent Literature 3: International Publication No. 2020/066457

### SUMMARY OF THE DISCLOSURE

The present disclosure is:

a fluororesin film that is a film comprising a fluororesin-containing composition, wherein at least one surface of the fluororesin film has an average value of contact angles for water measured at 5 points with intervals of 100 mm in a travel direction of 105° or less and an average value of contact angles for n-hexadecane measured at 5 points with intervals of 100 mm in the travel direction of 45° or less at locations of center and 100 mm from respective left and right ends.

### Advantageous Effect of the Disclosure

The fluororesin film of the present disclosure has the advantageous effect that the uniformity in adhesion strength of the film is high.

### DESCRIPTION OF EMBODIMENTS OF THE DISCLOSURE

Hereinafter the present disclosure will be described in more detail.

When the fluororesin film is used as a substrate for a metal-clad laminate, metal foil, other resin or the like may be stacked on the substrate. Since the fluororesin is inherently a resin with low adhesiveness to others, it may be required to improve the adhesiveness in the stacking.

To improve such adhesiveness, it is known to apply a surface treatment such as plasma treatment, corona treatment, sputtering treatment, or the like to the fluororesin film. However, in such a treatment, it is difficult to perform a uniform surface treatment, and unevenness in the treatment often occurs.

Meanwhile, when a fluororesin film is used in printed wiring boards, metal wirings formed at insufficient surface-treated places cause peeling after circuit formation and lead to a concern that the quality may not meet customer requirements. Thus, uneven adhesiveness is a major problem. To improve this problem, fluororesin films with a uniform surface state have been required.

In view of the above-mentioned problems, the present disclosure provides a fluororesin film having a uniform surface state such that contact angles for water are 105° or less and contact angles for n-hexadecane are 45° or less at locations of the center and 100 mm from respective left and right ends, which are due to a uniform surface treatment applied to the film.

Hereinafter, each of these points will be described in more detail.

### (Surface State of Fluororesin Film)

The fluororesin film of the present disclosure satisfies the requirement that contact angles for water are 105° or less and contact angles for n-hexadecane are 45° or less at locations of the center and 100 mm from respective left and right ends.

When a surface treatment is applied to improve the adhesiveness of the fluororesin film, the contact angle of the film surface for water or n-hexadecane is reduced. However, depending on the state of the surface treatment, the contact angle of the surface varies, and there are places where the contact angle is not sufficiently reduced. The present disclosure has improved this point and is characterized in that, in addition to a surface treatment with high uniformity is performed, a treatment method and/or a treatment condition in which the surface tension is sufficiently reduced for both water and organic solvents are selected as a type of surface treatment.

The surface treatment state of the film tends to have differences, particularly between the ends and the center of the film. The present disclosure is thus characterized by satisfying the above-mentioned contact angles at the ends as well as at the center.

The surface state of the fluororesin film of the present disclosure is that, at all three locations of center and 100 mm from respective left and right ends, the arithmetic average of contact angles for water measured at 5 points with intervals of 100 mm in the travel direction is 105° or less, and the arithmetic average of contact angles for n-hexadecane measured at 5 points with intervals of 100 mm in the travel direction is 45° or less.

The fluororesin film of the present disclosure may have both surfaces satisfying the above-mentioned parameters or only one surface satisfying the above-mentioned parameters.

### (Fluororesin Film)

It is preferable that the fluororesin film of the present disclosure is a long film. The long film has a width direction and a length direction, and the length direction is the direction of the long length. Then, three positions of the center and locations of 100 mm from both ends in the width direction were set as measurement positions.

At each of the three measurement locations, contact angles at 5 points with intervals of 100 mm in the length direction from a measurement point of any position set as the first measurement point are measured, and the average of the measured values is taken as the contact angle in the present disclosure.

The contact angles at 5 points are measured at each of the three positions in the width direction, but in terms of the length direction, the contact angles of the 5 points are measured at the same position and averaged.

When the contact angles for water and n-hexadecane are measured at 5 points in this way, the contact angles are 105° or less and 45° or less, respectively. By this configuration, the above-mentioned problems are solved. Although the details of the relationship between water and n-hexadecane in terms of adhesion strength are unknown, it is presumed that a certain range is preferable from the following viewpoint.

The reduction in the contact angle for water suggests that there are many polar components (functional groups) that have strong interaction with water in the surface of the film, and the reduction in the contact angle for n-hexadecane suggests that there are many non-polar components that have strong interaction with n-hexadecane in the surface. Adhesion requires high wettability to increase the contact area with the mating material and strong adhesion between the substrates with chemical bonding, anchoring effects, and the like. Since fluorine has low wettability to any material, it is presumed that increasing the wettability by increasing the interactions with both polar and non-polar components is a factor that improves the adhesion strength.

In the present disclosure, the contact angle is a static contact angle, and the static contact angle is measured by the following method using a fully automatic contact angle meter DropMaster 700 (made by Kyowa Interface Science Co., Ltd.). A 2 μL of solution is dropped from a microsyringe to a horizontally-placed substrate, and a still image after 1 second from dropping is taken with a video microscope to determine a contact angle. The static contact angle is measured at the predetermined points, and an average value of the measured values is calculated and used.

The average value of the contact angle for water is more preferably 105° or less, further preferably 100° or less, and still further preferably 90° or less. The average value of the contact angle for n-hexadecane is more preferably 45° or less, further preferably 40° or less, and still further preferably 35° or less. The method for producing a fluororesin film having such contact angles is described in detail below.

It is preferable that the fluororesin film of the present disclosure has a thickness of 5 to 150 μm. The film having the thickness in such a range is preferable from the viewpoint of having sufficient properties as a substrate film. The lower limit of the thickness is more preferably 5 μm and further preferably 10 μm. The upper limit of the thickness is more preferably 150 μm and further preferably 100 μm.

In the present disclosure, for the thickness of the film, thicknesses of 12 points are measured at every 200 mm in the travel direction at every 5 mm in the width direction. Then, in the same width direction, the thicknesses of 12 points in the travel direction are arithmetically averaged. The obtained values are average film thicknesses in the travel direction each measured at every 5 mm in the width direction. Then, the arithmetic average value of all values of the average film thicknesses in the travel direction measured at every 5 mm in the width direction in this way is taken as average film thickness of entire surface.

When comparing the average film thickness obtained in this way to each average film thickness in the traveling direction every 5 mm in the width direction, it is preferable that each average film thickness in the traveling direction every 5 mm in the width direction is all within the range of the average film thickness of entire surface +2 μm.

This means that the film has an extremely high uniformity in thickness. When a long film with such a high uniformity is taken up, since the difference in thickness in that state is small, a film with high uniformity can be taken up in an excellent state. This is preferable in that it is difficult to cause problems in the subsequent process of lamination with metal foil, and further in that the characteristic impedance can be in an excellent range.

The film having high uniformity in terms of both the surface treatment state and the thickness of the film is preferable in that uniform adhesion can be achieved, especially in applications where the film is bonded to metal foil.

It is preferable that the fluororesin film of the present disclosure is a long film. More specifically, it is preferable that the width is 400 mm or more and the length is 3 m or more. From the viewpoint of productivity, it is more preferable that the width is 500 mm or more. It is also more preferable that the length is 10 m or more. Such a long film is preferably a roll film.

### (Fluororesin)

It is preferable that the number of unstable functional groups of the fluororesin constituting the fluororesin film of the present disclosure is small. Such fluororesin is produced by a method including adjusting conditions in production (in polymerization reaction) a method of subjecting a fluororesin after polymerization to fluorine gas treatment (fluorination), heat treatment, supercritical gas extraction, and the like to reduce the number of unstable functional groups, and the like. Fluorine gas treatment is preferred because it is excellent in processing efficiency and part or all of the unstable functional groups are converted into —CF₃ to form a stable terminal group. It is preferable to use fluororesin in which the number of unstable functional groups is reduced because dielectric loss tangent is reduced and loss of electric signals is reduced.

It is preferable that the number of unstable functional groups of the fluororesin of the present disclosure is less than 350 per 1×10⁶ carbon atoms in a main chain of the fluororesin. With such a small number of unstable functional groups, gas generation during melt forming can be suppressed, and it is possible to suppress thickness deviation due to the uneven flow of melted resin caused by gas stagnating near the slit of the T-die.

The number of unstable functional groups is more preferably less than 250, further preferably less than 100, still further preferably less than 20, and most preferably less than 10 per 1×10⁶ carbon atoms in the main chain of the fluororesin.

Specific examples of unstable functional groups include functional groups such as —COF, —COOH free, —COOH bonded, —CH₂OH, —CONH₂, and —COOCH₃.

The number of unstable functional groups is specifically measured by the following method. First, the fluororesin is melted and compression-molded to prepare a film having a thickness of 0.25 to 0.3 mm. The film is analyzed by Fourier transform infrared spectrophotometry to obtain an infrared absorption spectrum of the fluororesin, and a differential spectrum relative to a base spectrum of resin which is completely fluorinated and has no functional group is obtained. The number of unstable functional groups per 1×10⁶ carbon atoms in the main chain of the fluororesin is calculated from the peak of absorption of a specific functional group appearing in the differential spectrum based on the following formula (A).

$$N = I \times K / t \qquad ( A )$$

I: Absorbance

K: Coefficient of compensation

t: Thickness of film (mm)

The absorption frequency, molar extinction coefficient and coefficient of compensation for the unstable functional group in the present description will be described in Table 1 for reference. The molar extinction coefficient is determined from the FT-IR data of a model low molecular weight compound.

TABLE 1

| Unstable | Absorption | Molar extinction | | |
|---|---|---|---|---|
| terminal | frequency | coefficient | Coefficient of | Model |
| group | (cm−1) | (1/cm/mol) | compensation | compound |
| —COF | 1883 | 600 | 388 | C₇F₁₅COF |
| —COOH (free) | 1815 | 530 | 439 | H(CF₂)₆COOH |
| —COOH (bonded) | 1779 | 530 | 439 | H(CF₂)₆COOH |
| —COOCH3 | 1795 | 680 | 342 | C₇F₁₅COOCH₃ |
| —CONH2 | 3436 | 506 | 460 | C₇F₁₅CONH₂ |
| —CH2OH | 3648 | 104 | 2236 | C₇F₁₅CH₂OH |
| —CF2H | 3020 | 8.8 | 26485 | H(CF₂CF₂)₃CH₂OH |
| —OC(═O)O—R | 1817 | — | 1426 | — |

The above fluorination may be performed by bringing fluororesin which has not been fluorinated into contact with a fluorine-containing compound.

Examples of fluorine-containing compounds described above include, but are not limited to, a source of fluorine radicals, which generates a fluorine radical under conditions of fluorination. Examples of sources of fluorine radicals include F₂ gas, CoF₃, AgF₂, UF₆, OF₂, N₂F₂, CF₃OF and fluorinated halogen (e.g., IF₅, ClF₃).

While the concentration of the above source of fluorine radicals such as F₂ gas may be 100%, the source is used after being mixed with inert gas and diluted to preferably 5 to 50% by mass, more preferably 15 to 30% by mass. Examples of inert gas described above include nitrogen gas, helium gas and argon gas, and nitrogen gas is preferred from the economic point of view.

The condition of fluorination is not limited. Molten fluorine resin may be brought into contact with a fluorine-containing compound at usually the melting point of the fluorine resin or lower, preferably a temperature of 20 to 220° C. and more preferably 100 to 200° C. The time of fluorination is usually 1 to 30 hours, and preferably 5 to 25 hours. For the above fluorination, it is preferable that fluorine resin which has not been fluorinated is brought into contact with fluorine gas (F₂ gas).

In the present description, the content of the respective monomer units constituting fluorine resin may be calculated by appropriately combining NMR, FT-IR, elemental analysis and fluorescent X-ray analysis depending on the type of monomers.

The resin constituting the fluororesin film of the present disclosure is not limited and may be a polymer including a fluorine atom. A fluororesin which can be melt molded is more preferred as fluororesin. Examples thereof include a tetrafluoroethylene. perfluoroalkyl vinyl ether copolymer (PFA), a copolymer including a chlorotrifluoroethylene (CTFE) unit (CTFE copolymer), a tetrafluoroethylene. hexafluoropropylene copolymer (FEP), a tetrafluoroethylene·ethylene copolymer (ETFE), polychlorotrifluoroethylene (PCTFE), a chlorotrifluoroethylene. ethylene copolymer (ECTFE), polyvinylidene fluoride (PVDF), polyvinyl fluoride (PVF), a tetrafluoroethylene·hexafluoropropylene·vinylidene fluoride copolymer (THV) and a tetrafluoroethylene. vinylidene fluoride copolymer.

Of these fluororesins which can be melt molded, a tetrafluoroethylene. perfluoroalkyl vinyl ether copolymer (PFA) and a tetrafluoroethylene. hexafluoropropylene copolymer (FEP) are preferred.

Use of the above fluororesin which can be melt molded allows melt molding, and thus the cost of processing can be lower than cases using PTFE. Furthermore, adhesiveness when bonding to metal foil can be improved.

The above PFA has a melting point of preferably 180 to 340° C., more preferably 230 to 330° C. and further preferably 280 to 320° C. The above melting point corresponds to the local maximum value in a heat-of-fusion curve when temperature is increased at a rate of 10° C./minute using a differential scanning calorimeter (DSC).

The above PFA is not limited, and a copolymer in which the molar ratio between the TFE unit and the PAVE unit (TFE unit/PAVE unit) is 70/30 or more and less than 99.5/0.5 is preferred. The molar ratio is more preferably 70/30 or more and 98.9/1.1 or less, and further preferably 80/20 or more and 98.5/1.5 or less. When the ratio of the TFE unit is very low, mechanical properties tend to be reduced. When the ratio of the TFE unit is very high, the resin has extremely high melting point and moldability tends to be reduced. The above PFA may be a copolymer consisting of only TFE and PAVE or is preferably a copolymer in which the ratio of the monomer unit derived from a monomer copolymerizable with TFE and PAVE is 0.1 to 10% by mole and the total of the TFE unit and the PAVE unit is 90 to 99.9% by mole. Examples of monomers copolymerizable with TFE and PAVE include HFP, a vinyl monomer represented by CZ₃Z₄═CZ₅(CF₂)ₙZ₆ (in which Z₃, Z₄ and Z₅ are the same or different and represent a hydrogen atom or a fluorine atom, Z₆ represents a hydrogen atom, a fluorine atom or a chlorine atom, and n represents an integer of 2 to 10), and an alkyl perfluorovinyl ether derivative represented by CF₂═CF—OCH₂—Rf₇ (in which Rf₇ represents a perfluoroalkyl group having 1 to 5 carbon atoms). Examples of other copolymerizable monomers include a cyclic hydrocarbon monomer having an acid anhydride group. Examples of acid anhydride monomers include itaconic anhydride, citraconic anhydride, 5-norbornene-2, 3-dicarboxylic anhydride and maleic anhydride. One of the acid anhydride monomers may be used alone or two or more of them may be used in combination.

The above PFA has a melt flow rate (MFR) of preferably 0.1 to 100 g/10 minutes, more preferably 0.5 to 90 g/10 minutes, and further preferably 1.0 to 85 g/10 minutes. In the present description, MFR is obtained by measurement in accordance with ASTM D3307 under conditions of a temperature of 372° C. and a load of 5.0 kg.

The above FEP is not limited and a copolymer in which the molar ratio between the TFE unit and the PAVE unit (TFE unit/PAVE unit) is 70/30 or more and less than 99/1 is preferred. The molar ratio is more preferably 70/30 or more and 98.9/1.1 or less, and further preferably 80/20 or more and 97/3 or less. When the ratio of the TFE unit is very low, mechanical properties tend to be reduced. When the ratio of the TFE unit is very high, the resin has extremely high melting point and moldability tends to be reduced. FEP is also preferably a copolymer in which the ratio of the monomer unit derived from a monomer copolymerizable with TFE and HFP is 0.1 to 10% by mole and the total of the TFE unit and the HFP unit is 90 to 99.9% by mole. Examples of monomers copolymerizable with TFE and HFP include an alkyl perfluorovinyl ether derivative.

The above FEP has a melting point of preferably 150 to 320° C., more preferably 200 to 300° C. and further preferably 240 to 280° C. The above melting point corresponds to the local maximum value in a heat-of-fusion curve when temperature is increased at a rate of 10° C./minute using a differential scanning calorimeter (DSC).

The above FEP has MFR of preferably 0.01 to 100 g/10 minutes, more preferably 0.1 to 80 g/10 minutes, further preferably 1 to 60 g/10 minutes, and particularly preferably 1 to 50 g/10 minutes.

The fluororesin film according to the present disclosure may include a component other than fluororesin. Examples of components which the film may include, but are not limited to, a filler such as silica particles and glass staple fiber and thermosetting resin and thermoplastic resin which do not contain fluorine. The content of the components other than the fluororesin is preferably 5% by mass or less (further preferably 3% or less, 1% or less, or the like).

The fluororesin-containing composition according to the present disclosure may include spherical silica particles. Spherical silica particles improve flowability of resin, and molding is easy even when a large amount of silica is mixed.

The above spherical silica particles mean those which are substantially a sphere, and have a sphericity of preferably 0.80 or more, more preferably 0.85 or more, further preferably 0.90 or more, and most preferably 0.95 or more. Sphericity is calculated from the area and the circumference of a particle observed in a micrograph taken by SEM based on (sphericity)={4π×(area)÷(circumference) 2}. A sphericity close to 1 means that the particle is close to a sphere. More specifically, an arithmetic average value of 100 particles measured using an image processing device (FPIA-3000 made by Spectris) is used.

The spherical silica particle preferably has a D90/D10 of 2 or more (preferably 2.3 or more, 2.5 or more) and D50 of 10 μm or less when volumes of particles with small particle size are integrated. The spherical silica particle has a D90/D50 of preferably 1.5 or more (more preferably 1.6 or more). The spherical silica particle has a D50/D10 of preferably 1.5 or more (more preferably 1.6 or more). Spherical silica particles with small particle size can enter into the gap between spherical silica particles with large particle size, and this provides excellent filling properties and improves flowability. In particular, it is preferable that in the particle size distribution, frequencies at the side of small particle size are high compared to the Gaussian curve. The particle size may be measured by a laser diffraction scattering particle size distribution meter. Furthermore, it is preferable that coarse particles with a predetermined particle size or more are removed by a filter and the like.

The above spherical silica particle has a water absorption of preferably 1.0% or less, and more preferably 0.5% or less. Water absorption is based on the mass of dried silica particles. For the measurement of water absorption, a dried sample is left at 40° C. and 80% RH for 1 hour and the content of water generated when the sample is heated at 200° C. is measured by a Karl Fischer moisture analyzer, and water absorption is calculated.

For the above spherical silica particles, the fluororesin composition is heated at 600° C. for 30 minutes in air to burn the fluororesin and the spherical silica particles are collected, and then the above parameters may be measured using the above method.

The silica powder according to the present disclosure may be surface-treated. Previous surface treatment can suppress aggregation of silica particles and allows silica particles to be dispersed well in the resin composition.

The above surface treatment is not limited and any known surface treatment may be used. Specific examples include a treatment using a silane coupling agent such as epoxy silane, amino silane, vinyl silane and acrylic silane having a functional group, hydrophobic alkyl silane, phenyl silane and fluorinated alkyl silane, a plasma treatment and a fluorination treatment.

Examples of silane coupling agents described above include epoxy silane such as γ-glycidoxypropyl triethoxysilane and β-(3,4-epoxycyclohexyl) ethyltrimethoxysilane, amino silane such as aminopropyl triethoxysilane and N-phenylaminopropyl trimethoxysilane, vinyl silane such as vinyl trimethoxysilane and acrylic silane such as acryloxy trimethoxysilane.

For the above spherical silica, commercially available silica particles which satisfy the above features may also be used. Examples of commercially available silica particles include Denka Fused Silica FB Grade (made by Denka Company Limited), Denka Fused Silica SFP Grade (made by Denka Company Limited), EXCELICA (made by Tokuyama Corporation), high purity synthesized spherical silica ADMAFINE (made by Admatechs company limited), ADMANANO (made by Admatechs company limited) and ADMAFUSE (made by Admatechs company limited).

When the spherical silica is mixed, in the mixing amount thereof, the mixing ratio of silica is preferably 5% by mass or less (further preferably 3% or less, 1% or less, or the like) with respect to the mass of the fluororesin long film.

### (Oxygen Element Percentage of Surface)

In the film according to the present disclosure, it is preferable that an oxygen element percentage as measured when heat treatment is performed at 180° C. for 3 minutes, and then the state of one or both surfaces of the film is observed by ESCA is 1.35 atom % or more. The above-described oxygen element percentage is more preferably 1.5 atom % or more, further preferably 1.8 atom % or more, and most preferably 2.0 atom % or more.

In the fluororesin film of the present disclosure, it is preferable to increase the oxygen element percentage by applying a surface treatment such as plasma treatment to have a predetermined contact angle in the surface. Accordingly, in the fluororesin film of the present disclosure, a film obtained by extrusion or a film obtained by applying a liquid composition containing fluororesin powder to a substrate and drying is subjected to a surface treatment to increase the oxygen element percentage and improve the adhesiveness and to set the oxygen element percentage of the surface within the above-described range.

The film according to the present disclosure may be a fluorine film in which a difference between the oxygen element percentage when the state of surface of the film is observed by scanning X-ray photoelectron spectroscopy (XPS/ESCA) and the oxygen element percentage measured by scanning X-ray photoelectron spectroscopy (XPS/ESCA) after etching the film by argon gas cluster ion beams at an incident angle of 45° in the direction of the depth for 15 minutes is 1.0 atom % or more. By increasing the oxygen element percentage only on the surface which contributes to adhesion, sufficient adhesion strength can be achieved without reducing dielectric properties.

The heat treatment at 180° C. for 3 minutes means that the film is put on a metal tray and heat-treated in an electric oven in air atmosphere.

In the fluororesin film according to the present disclosure, it is preferable that an absolute value of the rate of dimensional change in MD and TD before and after heat treatment is 2.0% or less as measured when the film is heat-treated at 180° C. for 10 minutes and then cooled to 25° C. The fluororesin film has a rate of dimensional change of more preferably 1.8% or less, and most preferably 1.5% or less. In the present disclosure, for the rate of dimensional change, marks are put at intervals of 180 mm on a film sample which has been cut into a 300 mm square, the sample is heat treated for 10 minutes in air atmosphere in an electric oven set at 180° C. without load and cooled to 25° C., and the distance between the marks on the film is measured in the MD direction and the TD direction respectively and the rate of dimensional change is calculated from the amount of change in the distance between the marks before and after the heat treatment.

To obtain a fluororesin film having such a rate of dimensional change, it is preferable to perform an annealing treatment as described in detail below.

It is more preferable that the resin film of the present disclosure has a dielectric loss tangent at 10 GHz of less than 0.0015. The dielectric loss tangent in that range is preferred because loss of electric signals in the circuit can be kept low. The fluororesin film has a dielectric loss tangent of more preferably less than 0.0013, and further preferably less than 0.0010.

To set the dielectric loss tangent to the above range, it is preferable to use resin in which the number of unstable functional groups is small. It is more preferable to use a fluororesin which has been fluorinated at the terminal.

The above fluororesin film preferably has an adhesion strength of 0.8 N/mm or more at locations of center and 100 mm from respective left and right ends of the fluororesin film when bonded to metal foil having a surface roughness Rz of 1.5 μm or less under conditions of a temperature of the melting point of the fluororesin or more and the melting point +30° C. or less, a pressure of 1.5 to 3.0 MPa and a time of 300 to 600 seconds using a vacuum heat press.

That is, the above fluororesin film has sufficient adhesion strength at both the center and the ends of the film, and has a high degree of uniformity in adhesiveness.

It should be noted that the adhesion strength as used herein means an arithmetic average of the measured values taken at 5 points with intervals of 100 mm in the travel direction as in the measurement of the contact angle.

It is preferable that the fluororesin film has adhesion strengths between a prepreg comprising a thermosetting resin and locations of center and 100 mm from respective left and right ends of the fluororesin film of 0.8 N/mm or more. The adhesion strength as used herein means the adhesion strength when bonded by the method described in Examples.

It should be noted that the adhesion strength also means the average value of the measured values taken at 5 points with intervals of 100 mm in the travel direction as in the measurement of the contact angle.

It is preferable that the one or both surfaces of the above fluororesin film have an adhesion strength of more than 30 N/m when the surfaces of the film are mutually bonded at 200° C. A fluororesin with such adhesion strength has excellent adhesiveness when used in combination with other substrates even after heat treating the fluororesin film. The fluororesin film has an adhesive strength of preferably more than 50 N/m and more preferably more than 100 N/m.

### (Method for Producing Fluororesin Film of Present Disclosure)

The fluororesin film of the present disclosure is generally produced by extrusion melt forming in which a melted resin is extruded from a T-die into a film shape, cooled, and then taken up.

The fluororesin film of the present disclosure is primarily characterized by the method of surface treatment. However, when the resin film to be subjected to the surface treatment is a film with high uniformity, it is preferable in that the uniformity of the entire film becomes high. It is thus preferable to employ a method for producing a fluororesin film having particularly less thickness unevenness.

With such a viewpoint, in the extrusion melt forming, the thickness of the resin film is particularly affected by the air gap distance from the end where the resin in a T-die flows out to a point where the resin contacts with the first roll, the MFR of the resin used, the melting temperature during film production, the pressure, the slit width of the T-die, the gap width, and the like. Accordingly, adjusting these appropriately can provide a smooth resin film satisfying the parameters described above.

Furthermore, adjusting MFR is also preferable. That is, shortening the air gap reduces the thickness unevenness of the film by reducing the interposition of an air layer between the melt and the first roll.

The method of surface modification is not limited, and the surface may be modified by any known method. For surface modification of fluororesin film, a traditional discharge treatment such as a corona discharge treatment, a glow discharge treatment, a plasma discharge treatment and a sputtering treatment may be used. For example, surface free energy may be controlled by introducing, for example, oxygen gas, nitrogen gas or hydrogen gas into discharge atmosphere. Alternatively, the surface to be modified is exposed to atmosphere of an organic compound-containing inert gas, and high frequency voltage is applied between electrodes to generate discharge and form active species on the surface. Then the functional group of the organic compound is introduced thereinto or a polymerizable organic compound is graft-polymerized to allow the surface modification. Examples of inert gases described above include nitrogen gas, helium gas and argon gas.

Examples of organic compounds in the organic compound-containing inert gas include polymerizable or non-polymerizable oxygen atom-containing organic compounds such as vinyl esters such as vinyl acetate and vinyl formate; acrylates such as glycidyl methacrylate; ethers such as vinyl ethyl ether, vinyl methyl ether and glycidyl methyl ether; carboxylic acids such as acetic acid and formic acid; alcohols such as methyl alcohol, ethyl alcohol, phenol and ethylene glycol; ketones such as acetone and methyl ethyl ketone; carboxylates such as ethyl acetate and ethyl formate; and acrylic acids such as acrylic acid and methacrylic acid. Of them, vinyl esters, acrylates and ketones are preferred, and in particular vinyl acetate and glycidyl methacrylate are preferred because the modified surface is less likely to be deactivated, i.e., has long life and can be easily handled.

The concentration of the organic compound in the above organic compound-containing inert gas varies depending on its type and the type of fluororesins of which surface is to be modified. The concentration is usually 0.1 to 3.0% by volume, and preferably 0.1 to 1.0% by volume. Conditions of discharge may be appropriately selected depending on the intended degree of surface modification, the type of fluororesins and the type and the concentration of organic compounds. Usually the discharge treatment is performed in the amount of discharge of 50 to 1500 W·minute/m², and preferably 70 W·minute/m² or more and 1400 W·minute/m² or less. The discharge treatment may be performed at any temperature of 0° C. or more to 100° C. or less. The temperature is preferably 80° C. or less in consideration of elongation and wrinkles of film.

In the above surface modification, it is preferable that the discharge treatment is performed at a discharge degree, which indicates the output per unit area, in the range of 1.0 to 10 (W/cm²) while adjusting the gas concentration/line speed ratio to the range of 0.005 to 0.05 (L/m).

The gas concentration/line speed ratio herein is a ratio of the concentration of an organic compound in the organic compound-containing inert gas divided by the line speed. When the gas concentration/line speed ratio is below 0.005 (L/m), there is insufficient gas in the space relative to the conveying speed, and the activated gas is less likely to contact the surface of the film, reducing the in-plane uniformity. When the gas concentration/line speed ratio is above 0.05 (L/m), the surface is over-treated and damaged, so that the low molecular weight compounds are generated on the surface, resulting in the formation of a fragile layer, which in turn leads to a reduction in adhesion strength. Thus, the treatment within the above-described range is particularly preferable, since it is presumed that the surface of the film is more uniformly treated and a predetermined adhesiveness can be obtained.

For the degree of surface modification, an abundance of oxygen element in observation by ESCA is 2.0% or more, preferably 2.5% or more, more preferably 3.0% or more, and further preferably 3.5% or more in consideration of reduction of adhesiveness on the surface due to heat in post-processing. The upper limit is not limited, but is preferably 25.0% or less in consideration of productivity and impacts on other physical properties. The abundance of nitrogen element is not limited, but is preferably 0.1% or more. The fluororesin film has a thickness of preferably 2.5 to 1, 000 μm, more preferably 5 to 500 μm and further preferably 7 to 150 μm per film.

Such treatment may be performed only on one side of the film or on both sides of the film.

### (Annealing Treatment)

The fluororesin film of the present disclosure may be one subjected to an annealing treatment after the above surface treatment. As described above, it is preferable that the fluororesin film of the present disclosure has dimensional stability at the time of lamination with metal foil. It is thus preferable that the fluororesin film has a small shrinkage rate during heating.

Fluororesin films obtained by extrusion melt forming often have heat shrinkage due to residual internal stress. Such heat shrinkage adversely affects the dimensional stability when bonded to metal foil. It is thus preferable to release internal stress by performing an annealing treatment. Annealing treatment may be performed by heat treatment. In this heat treatment, for example, film may be passed through a heating furnace by a roll-to-roll method.

It is preferable that in the production of the fluororesin film of the present disclosure, annealing treatment is performed after the above corona discharge treatment. Furthermore, heat treatment may be performed in the process of lamination of the film and other materials such as metal foil. These heat treatments cause a reduction in the amount of oxygen on the surface of the fluororesin film. Thus, it is preferable to modify the surface under conditions that provide a sufficient amount of oxygen on the surface when the fluororesin film and other materials such as metal foil are actually stacked.

The temperature of annealing treatment is preferably the glass transition temperature −20° C. or more and less than the melting point, more preferably the glass transition temperature or more and the melting point −20° C. or less, and further preferably the glass transition temperature or more and the melting point −60° C. or less. The time of annealing treatment is not limited, and may be appropriately adjusted to, for example, 0.5 to 60 minutes.

When the film is heated by the above roll-to-roll method, the tension may be appropriately set depending on the thickness of the film and the set temperature, and is preferably 20 N/m or less. Heating under these conditions is preferable because internal stress can be sufficiently released and dimensional change and the like does not occur.

The order of the above surface treatment and annealing treatment is not limited. The number of times of the respective steps to be executed is not limited to once, either, and may be executed twice or more.

The present disclosure also includes a laminate in which metal foil is bonded to one or both surfaces of the above fluororesin film. As described above, the film comprising the fluororesin of the present disclosure has excellent adhesiveness. It is preferable that the above metal foil has Rz of 1.5 μm or less. In other words, the fluororesin composition according to the present disclosure has excellent adhesion even to highly smooth metal foil having Rz of 1.5 μm or less. The metal foil may have Rz of 1.5 μm or less on at least the surface to be bonded to the above fluororesin film, and the value of Rz on the other surface is not limited.

The thickness of the metal foil is not limited, and the copper foil has a thickness of preferably 1 to 100 μm, more preferably 5 to 50 μm, and further preferably 9 to 35 μm.

The metal foil described above is not limited, but is preferably copper foil. The above copper foil is not limited and specific examples thereof include rolled copper foil and electrolytic copper foil.

Copper foil having Rz of 1.5 μm or less is not limited and commercially available copper foil may be used. Examples of commercially available copper foil having Rz of 1.5 μm or less include electrolytic copper foil CF-T9DA-SV-18 (thickness 18 μm, Rz 0.85 μm) (made by Fukuda Metal Foil & Powder Co., Ltd.).

The above metal foil may be surface-treated to improve adhesion strength to the fluororesin film of the present disclosure.

The surface treatment includes, but is not limited to, a silane coupling treatment, a plasma treatment, a corona treatment, a UV treatment and an electron beam treatment. The reactive functional group of the silane coupling agent is not limited, and the silane coupling agent may preferably include at least one group selected from an amino group, a (meth) acrylic group, a mercapto group and an epoxy group at the terminal in view of adhesion to the resin substrate. Examples of hydrolytic groups include, but are not limited to, an alkoxy group such as a methoxy group and an ethoxy group. An anti-rust layer (an oxide coating such as chromate) and a heat resistant layer may be formed on the metal foil used in the present disclosure.

Surface-treated metal foil having a surface-treated layer of the above silane compound on the surface may be produced by preparing a solution containing a silane compound and surface treating the metal foil using the solution.

The metal foil may have a roughened layer on the surface in order to increase adhesion to the resin substrate and the like.

If roughening treatment is likely to degrade properties required in the present disclosure, the amount of roughening particles to be electrodeposited on the metal foil surface may be reduced if necessary, or roughening treatment may not be performed.

One or more layers selected from a heat-resisting treated layer, an anti-rust layer and a chromate-treated layer may be formed between the metal foil and the surface-treated layer in order to improve various properties. Those layers may be a single layer or multiple layers.

It is preferable that the above laminate has an adhesion strength between the metal foil and the fluororesin film of 0.8 N/mm or more. Using the method described above allows the laminate to have such adhesion strength. By setting the adhesion strength to 0.9 N/mm or more, or 1.0 N/mm or more, the laminate may be suitably used as a metal-clad laminate or a substrate for circuits. The adhesion strength as used herein means the adhesion strength measured under conditions described in Examples. In the case of a laminate prepared by bonding metal foil to the surface-treated side of a fluororesin film having only one side surface-treated, the non-treated side of the fluororesin film may also be surface-modified in order to improve adhesiveness of the laminate to other materials.

Examples of methods for producing a laminate include a method of stacking metal foil to the surface of a film, an evaporation method, and a plating method. Examples of methods for stacking metal foil include a method by heat pressing and a method by roll-to-roll lamination.

When stacking by heat pressing, examples of temperature include a melting point of dielectric film −150° C. to a melting point of dielectric film +40° C. Examples of time of heat pressing include 1 to 30 minutes. The pressure of heat pressing can be produced by the method of 0.1 to 10 MPa.

When stacking by roll-to-roll lamination, examples of temperature include a melting point of dielectric film −150° C. to a melting point of dielectric film +40° C. The speed is preferably 0.5 m/min or more, and more preferably 1.0 m/min or more from the viewpoint of productivity.

The pressure is preferably in the range of 10 kg/cm to 200 kg/cm, but 20 kg/cm or more is more preferable for excellent adhesiveness. The device of roll-to-roll lamination is not limited, but it is desirable that the device has one or more pairs of metal nip rolls, or nip rolls having a rubber roll on one side.

The laminate is preferably a long laminate. More specifically, it is preferable that the laminate has the width of 400 mm or more and the length of 3 m or more. From the viewpoint of productivity, the width is more preferably 500 mm or more. The length is more preferably 10 m or more. It is preferable that such a long laminate is a roll laminate.

The metal-clad laminate of the present disclosure may further have a layer other than the metal foil or the fluororesin film.

It is preferable that the layer other than the metal foil or the fluororesin film is at least one selected from the group consisting of polyimide, liquid crystal polymer, polyphenylene sulfide, a cycloolefin polymer, polystyrene, epoxy resin, bismaleimide, polyphenylene oxide, polyphenylene ether, and polybutadiene.

The layer other than the metal foil or the fluororesin film is not limited as long as it comprises the resin described above. It is also preferable that the layer other than the metal foil or the fluororesin film has a thickness in the range of 12 to 200 μm.

In the metal-clad laminate of the present disclosure, a metal layer is formed on the surface of the film of the present disclosure. The metal layer can be formed on one side or both sides of the film. Examples of methods for forming a metal layer include a method of stacking metal foil to the surface of a film, an evaporation method, and a plating method. Examples of methods for stacking metal foil include a method by heat pressing and a method by roll-to-roll lamination.

The method for forming a composite of the metal foil, a substrate layer and the fluororesin film is not limited, and includes the following two.

(i) A method in which metal foil, a substrate layer and a fluororesin film which has been previously formed are stacked by applying pressure using a roll-to-roll process or a pressing machine while heating. The layer facing the metal foil may be the substrate layer or the fluororesin layer.

(ii) A method in which a laminate having a fluororesin film bonded to one side of metal foil is produced, and a side of the fluororesin film not facing the metal foil is stacked on the substrate layer by applying pressure while heating.

The application of the metal-clad laminate of the present disclosure is not limited, and the metal-clad laminate of the present disclosure is used as a substrate for circuits. A printed circuit board is a plate-like part that electrically connects electronic components such as semiconductors and capacitor chips while arranging and fixing those in a limited space. The configuration of the printed circuit board formed from the metal-clad laminate of the present disclosure is not limited. The printed circuit board may be a rigid circuit board, a flexible circuit board, or a rigid-flexible circuit board. The printed circuit board may be any of a single-sided substrate, a double-sided substrate, or a multilayer substrate (such as a build-up substrate). In particular, the metal-clad laminate of the present disclosure can be suitably used for flexible circuit boards and rigid circuit boards.

The substrate for circuits is not limited, and can be produced by general methods using the metal-clad laminate described above.

The laminate for a circuit board also includes a laminate comprising a metal foil layer, the above fluororesin film, and a substrate layer. The substrate layer is not limited. It is preferable that the laminate has a fabric layer made of glass fiber and a resin film layer.

The above fabric layer made of glass fiber is made of, for example, glass cloth or glass non-woven fabric. Commercially available glass cloth may be used, and glass cloth which has been treated with a silane coupling agent is preferred in order to improve affinity with fluororesin. Materials of glass cloth include E-glass, C-glass, A-glass, S-glass, D-glass, NE-glass and low dielectric glass. E-glass, S-glass and NE-glass are preferred because they are readily available. The type of weaving fiber may be plain weave or twill weave. The glass cloth has a thickness of usually 5 to 90 μm and preferably 10 to 75 μm. It is preferable to use the glass cloth thinner than the fluororesin film used.

For the above laminate, glass non-woven fabric may be used as the fabric layer made of glass fiber. Glass non-woven fabric refers to a fabric prepared by bonding glass staple fiber with a small amount of a binder compound (resin or an inorganic substance), or fabric in which pieces of glass staple fiber are entangled to maintain the shape without using a binder compound. Commercially available ones may be used. The glass staple fiber has a diameter of preferably 0.5 to 30 μm, and a fiber length of preferably 5 to 30 mm. Examples of binder compounds include a resin such as epoxy resin, acrylic resin, cellulose, polyvinyl alcohol and fluororesin, and an inorganic compound such as a silica compound. The amount of the binder compound used is usually 3 to 15% by mass based on the glass staple fiber. Materials of glass staple fiber include E-glass, C-glass, A-glass, S-glass, D-glass, NE-glass and low dielectric glass. The glass non-woven fabric has a thickness of usually 50 μm to 1, 000 μm, and preferably 100 to 900 μm. The thickness of the glass non-woven fabric in the present application refers to values measured according to JIS P8118:1998 using Digital Gauge DG-925 (load 110 g, diameter 10 mm) made by Ono Sokki Co., Ltd. To improve affinity with fluororesin, the glass non-woven fabric may be treated with a silane coupling agent.

Since most glass non-woven fabrics have a very high porosity of 80% or more, it is preferable to use a glass non-woven fabric thicker than the sheet of fluororesin; and it is preferable to compress glass non-woven fabric under pressure and then used.

The above fabric layer made of the glass fiber may be a layer in which glass cloth and glass non-woven fabric are stacked. This combines both features and provides suitable qualities.

The fabric layer made of the glass fiber may be in the form of prepreg which has been impregnated with resin.

In the above laminate, the fabric layer made of glass fiber may be bonded to the fluororesin film at the interface, or the fabric layer made of glass fiber may be partly or entirely impregnated with the fluororesin film.

Furthermore, prepreg may be prepared by impregnating fabric made of glass fiber with a fluororesin composition. The prepreg prepared as described above may be stacked with the fluororesin film of the present disclosure. In that case, the fluororesin composition used for preparing prepreg is not limited, and the fluororesin film of the present disclosure may be used.

Heat resistant resin film and thermosetting resin film are preferred as the resin film used as the above substrate. Examples of heat resistant resin film include polyimide, liquid crystal polymer and polyphenylene sulfide. Examples of thermosetting resins include those including epoxy resin, bismaleimide, polyphenylene oxide, polyphenylene ether and polybutadiene.

The heat resistant resin film and the thermosetting resin film may also include reinforcing fiber. Examples of reinforcing fibers include, but are not limited to, glass cloth, in particular preferably low dielectric glass cloth.

Properties of the heat resistant resin film and the thermosetting resin film, such as dielectric properties, linear expansion coefficient and water absorption ratio are not limited. For example, the dielectric constant at 20 GHz is preferably 3.8 or less, more preferably 3.4 or less and further preferably 3.0 or less. The dielectric loss tangent at 20 GHz is preferably 0.0030 or less, more preferably 0.0025 or less, and further preferably 0.0020 or less. The linear expansion coefficient is preferably 100 ppm/° C. or less, more preferably 70 ppm/° C. or less, and further preferably 40 ppm/° C. or less. The water absorption is preferably 1.0% or less, more preferably 0.5% or less, and further preferably 0.1% or less.

### EXAMPLES

The present disclosure will be described in more detail with reference to Examples. In the following Examples, the ratio is expressed as a molar ratio.

### Example 1

PFA (TFE/PPVE copolymer, composition: TFE/PPVE=98.2/1.8, MFR: 15.8 g/10 minutes, melting point 305° C., glass transition temperature 92° C.) as a fluororesin was fed into a 360° C. extruder, extruded from a 1,700 mm wide T die, picked up onto a metal cooling roll, and further taken up on a winding core to obtain a roll film of 1,300 mm width and 50 μm thickness. Both surfaces of the roll film were surface-treated (both surfaces of the film were subjected to corona discharge treatment by passing the film continuously along a roll-shaped ground electrode while flowing a nitrogen gas containing vinyl acetate so that the ratio of the gas concentration of vinyl acetate in the nitrogen gas to the line speed is 0.014 (L/m) near the discharge electrode and the roll-shaped ground electrode in a corona discharge device at a discharge degree of 1.4 W/cm²), and the surface-treated long film was taken up in the form of a roll to obtain a surface-treated sample. Then, the obtained sample was evaluated.

### Example 2

Example 2 was performed in the same manner as in Example 1 except that the discharge degree was set to 2.3 W/cm², and thus a surface-treated sample was obtained and then evaluated.

### Example 3

Example 3 was performed in the same manner as in Example 1 except that the discharge degree was set to 2.9 W/cm², and thus a surface-treated sample was obtained and then evaluated.

### Example 4

Example 4 was performed in the same manner as in Example 1 except that the discharge degree was set to 3.7 W/cm², and thus a surface-treated sample was obtained and then evaluated.

### Example 5

Example 5 was performed in the same manner as in Example 3 except that the gas concentration/line speed ratio was set to 0.007 L/m, and thus a surface-treated sample was obtained and then evaluated.

### Example 6

Example 6 was performed in the same manner as in Example 3 except using a film that underwent the step of slitting a long roll film of 1,300 mm width and 50 μm thickness obtained by T-die method to a width of 500 mm, and thus a surface-treated sample was obtained and then evaluated.

### Example 7

Example 7 was performed in the same manner as in Example 3 except using PFA (TFE/PPVE copolymer, composition: TFE/PPVE=97.7/2.3 MFR: 15.0 g/10 minutes, melting point 300.9° C., glass transition temperature 93° C.) as a fluororesin, and thus a surface-treated sample was obtained and then evaluated.

### Comparative Example 1

Comparative Example 1 was performed in the same manner as in Example 3 except that the gas concentration/line speed ratio was set to 0.004 L/m, and thus a surface-treated sample was obtained and then evaluated.

### Comparative Example 2

Comparative Example 2 was performed in the same manner as in Example 3 except that the discharge degree was set to 0.6 W/cm², and thus a surface-treated sample was obtained and then evaluated.

### Comparative Example 3

Comparative Example 3 was performed by evaluating a sample that had not undergone the surface treatment.

### (Static Contact Angle for Water)

The static contact angle for water was measured by the following method using a fully automatic contact angle meter DropMaster 700 (made by Kyowa Interface Science Co., Ltd.). 2 μL of water was dropped from a microsyringe to a horizontally-placed substrate, and a still image after 1 second from dropping was taken with a video microscope to determine a contact angle. The static contact angle for water was measured at 5 points with intervals of 100 mm in the travel direction at locations of the center and 100 mm from respective left and right ends. The average values thereof are shown in Table 2. It should be noted that the contact values shown in Table 2 are the initial values measured immediately after film production.

### (Static Contact Angle for N-hexadecane)

The static contact angle for n-hexadecane was measured by the following method using a fully automatic contact angle meter DropMaster 700 (made by Kyowa Interface Science Co., Ltd.). 2 μL of n-hexadecane was dropped from a microsyringe to a horizontally-placed substrate, and a still image after 1 second from dropping was taken with a video microscope to determine a contact angle. The static contact angle for n-hexadecane was measured at 5 points with intervals of 100 mm in the travel direction at locations of the center and 100 mm from respective left and right ends. The average values thereof are shown in Table 2. It should be noted that the contact values shown in Table 2 are the initial values measured immediately after film production.

### (Adhesion Strength to Copper Foil)

A film and electrolytic copper foil CF-T9DA-SV-18 (thickness 18 μm/Rz 0.85 μm) (made by Fukuda Metal Foil & Powder Co., Ltd.) were stacked in the order of the copper foil, the fluororesin film and the copper foil, and heat-pressed using a vacuum heat press (Model: MKP-1000HVWH-S7, made by Mikado Technos Co., Ltd.) at a press temperature of 320° C. for a preheating time of 60 seconds at a pressure of 1.5 MPa for a pressing time of 300 seconds to prepare a laminate. An aluminum plate was attached to one side of the laminate with adhesive tape, and peel strength was measured by sandwiching and pulling copper foil at a width of 10 mm in the direction at 90° relative to the plane of the laminate at a rate of 50 mm per minute using Tensilon Universal Testing Machine (made by Shimadzu Corporation). The resulting value was defined as adhesion strength. The measurement value is an average value of the measurement values taken at 5 points with intervals of 100 mm in the travel direction at all three locations of the center and 100 mm from respective left and right ends. The results are shown in Table 2.

### (Adhesion Strength to Prepreg)

A sample was prepared using prepreg R-5680 (J) (thickness 132 μm) (made by Panasonic Corporation) as the prepreg material under the press conditions of a temperature of 200° C., a time of 75 minutes, and a pressure of 3.0 MPa, and then the adhesion strength was measured in the same manner as the adhesion strength to copper foil. The measurement value is an average value of the measurement values taken at 5 points with intervals of 100 mm in the travel direction at all three locations of the center and 100 mm from respective left and right ends. The results are shown in Table 2.

### (Adhesion Strength Between Fluororesin Films)

A sample prepared by stacking the surface-treated surfaces of fluororesin films by a heat press (200° C., 0.1 MPa, 60 seconds) was cut into a 10-mm wide strip. Using Tensilon Universal Testing Machine (made by Shimadzu Corporation), the strip was pulled at a rate of 100 mm per minute while being held at the portion which had not been bonded with the upper and lower chucks of Tensilon to measure peel strength. The resulting value was defined as adhesion strength. The measurement value is an average value of the measurement values taken at 5 points with intervals of 100 mm in the travel direction at all three locations of the center and 100 mm from respective left and right ends. The results are shown in Table 2.

In Examples 1 and 7, the dielectric constant and the dielectric loss tangent were measured by a split cylinder resonator (10 GHZ).

### (Melting Point)

The melting point was calculated from the melting peak measured using a DSC apparatus while increasing the temperature at a temperature increase rate of 10° C./minute.

### (Glass Transition Temperature)

The glass transition temperature was calculated from the tan & peak measured using a solid dynamic mechanical analyzer (DMA) at a frequency of 10 Hz and a strain of 0.1% while increasing the temperature at a temperature increase rate of 5° C./minute. The results are shown in Table 2.

### (Number of Unstable Functional Groups)

For the number of unstable functional groups, the film was analyzed using FT-IR Spectrometer 1760X (made by Perkin-Elmer). The results are shown in Table 2.

### (Thickness of Fluororesin Film)

The thickness of the fluororesin film was measured by a micrometer. As shown in FIG. 1, the thickness was measured at 12 points of every 20 cm in the travel direction in the travel direction at every 5 mm in the width direction. The average of entire film thicknesses measured in this way was shown in the table as “average film thickness of surface”. Furthermore, each average thickness of 12 points in the travel direction measured at the same value in the width direction was calculated, and the difference between the maximum value among them and the average film thickness of surface was shown in the table.

### (ESCA Analysis of Surface of Fluororesin Film)

The surface of the fluororesin film was observed using scanning X-ray photoelectron spectroscopy (XPS/ESCA) PHI 5000 Versa Probe II (made by ULVAC-PHI, Inc.) with a source of monochromated Alka at an incident angle of 45°.

### (Dielectric Loss Tangent)

The dielectric loss tangent of the fluororesin film was measured by Split Cylinder Resonator CR-710 and CR-740 (made by EM Labs Inc.) at 10 GHZ (26° C.) and analyzed by Vector Network Analyzer P5007A (made by Keysight Technologies).

### (Rz)

Rz in the range of 200 μm² was measured using a color 3D laser microscope VK-9700 made by KEYENCE CORPORATION.

TABLE 2

| | | | | | | | | | | Com- | Com- | Com- |
|---|---|---|---|---|---|---|---|---|---|---|---|---|
| | | | | | | | | | | parative | parative | parative |
| | | | Exam- | Exam- | Exam- | Exam- | Exam- | Exam- | Exam- | Exam- | Exam- | Exam- |
| | | | ple 1 | ple 2 | ple 3 | ple 4 | ple 5 | ple 6 | ple 7 | ple 1 | ple 2 | ple 3 |
| Film | Resin | | PFA | ← | ← | ← | ← | ← | PFA | PFA | PFA | PFA |
| | Film width (mm) | | 1300 | ← | ← | ← | ← | 500 | 1300 | 1300 | ← | ← |
| | Number of | | 307 | ← | ← | ← | ← | ← | 8 | 307 | ← | ← |
| | unstable functional | | | | | | | | | | | |
| | groups per 1 × 10⁶ | | | | | | | | | | | |
| | carbon atoms | | | | | | | | | | | |
| | Average film | | 50 | ← | ← | ← | ← | ← | 50 | 50 | ← | ← |
| | thickness of | | | | | | | | | | | |
| | surface (μm) | | | | | | | | | | | |
| | Maximum value | | 51.6 | ← | ← | ← | ← | ← | 51.3 | 51.6 | ← | ← |
| | of average | | | | | | | | | | | |
| | film thicknesses | | | | | | | | | | | |
| | at each | | | | | | | | | | | |
| | position in | | | | | | | | | | | |
| | width direction | | | | | | | | | | | |
| | (average film | | | | | | | | | | | |
| | thicknesses in | | | | | | | | | | | |
| | travel direction | | | | | | | | | | | |
| | at every 5 mm | | | | | | | | | | | |
| | in width direction) | | | | | | | | | | | |
| Pro- | Discharge degree | | 1.4 | 2.3 | 2.9 | 3.7 | 2.9 | 2.9 | 2.9 | 2.9 | 0.6 | — |
| duction | (W/cm²) | | | | | | | | | | | |
| conditions | Gas concentration/ | | 0.014 | 0.014 | 0.014 | 0.014 | 0.007 | 0.014 | 0.014 | 0.004 | 0.014 | — |
| | line speed (L/m) | | | | | | | | | | | |
| ESCA | Oxygen | Center | 5.86 | 7.99 | 8.72 | 10.56 | 5.28 | 10.21 | 8.72 | 1.33 | 1.13 | 0.71 |
| | element | Right | 5.18 | 8.02 | 8.93 | 10.31 | 4.93 | 10.14 | 8.47 | 1.31 | 1.11 | 0.67 |
| | percentage | Left | 5.53 | 7.8 | 9.04 | 10.78 | 4.86 | 10.2 | 9.06 | 1.24 | 1.08 | 0.71 |
| | (%) | | | | | | | | | | | |
| Average | Water | Center | 89 | 86 | 84 | 80 | 90 | 82 | 93 | 96 | 106 | 114 |
| static | | Right | 92 | 85 | 85 | 82 | 92 | 82 | 92 | 98 | 106 | 114 |
| contact | | Left | 92 | 88 | 83 | 79 | 93 | 83 | 93 | 97 | 107 | 113 |
| angle | HD | Center | 28 | 29 | 27 | 27 | 30 | 25 | 30 | 43 | 47 | 52 |
| (°) | | Right | 33 | 30 | 26 | 35 | 40 | 26 | 31 | 47 | 48 | 52 |
| | | Left | 32 | 28 | 27 | 38 | 42 | 26 | 30 | 48 | 50 | 52 |
| Adhesion | Copper | Center | 1.1 | 1.2 | 1.3 | 1.1 | 1.1 | 1.3 | 1.2 | 0.8 | 0.3 | 0.1 |
| strength | foil | Right | 0.9 | 1 | 1.3 | 1 | 0.9 | 1.1 | 1.1 | 0.7 | 0.2 | 0 |
| (N/mm) | | Left | — | 1.1 | 1.2 | 1.1 | 1 | 1.2 | 1.2 | 0.6 | 0.2 | 0.1 |
| | Prepreg | Center | — | — | 1 | — | 0.9 | — | 1 | — | 0.2 | — |
| | | Right | — | — | 1.1 | — | 0.8 | — | 1 | — | 0.1 | — |
| | | Left | — | — | 1 | — | 0.8 | — | 0.9 | — | 0.3 | — |
| Adhesion | Between | Center | — | — | 260 | — | — | — | 250 | — | — | 10 |
| strength | surfaces | Right | — | — | 250 | — | — | — | 240 | — | — | 10 |
| (N/m) | of film | Left | — | — | 250 | — | — | — | 250 | — | — | 10 |

| | | | | | | | | | | | |
|---|---|---|---|---|---|---|---|---|---|---|---|
| Electric | Dielectric constant | 2.05 | ← | ← | ← | ← | ← | 2.02 | — | — | — |
| properties | Dielectric loss | 0.00105 | ← | ← | ← | ← | ← | 0.00029 | — | — | — |
| | tangent (tan δ) | | | | | | | | | | |

From the results of Table 2, it is clear that the fluororesin film of the present disclosure has high uniformity in adhesion strength.

### INDUSTRIAL APPLICABILITY

The fluororesin film of the present disclosure can be used for a metal-clad laminate for a substrate for circuit, or the like.

1. A fluororesin film that is a film comprising a fluororesin-containing composition,
wherein at least one surface of the fluororesin film has an average value of contact angles for water measured at 5 points with intervals of 100 mm in a travel direction of 105° or less and an average value of contact angles for n-hexadecane measured at 5 points with intervals of 100 mm in the travel direction of 45° or less at locations of center and 100 mm from respective left and right ends.

2. The fluororesin film according to claim 1, wherein the fluororesin film has a film width of 400 mm or more.

3. The fluororesin film according to claim 1, wherein the fluororesin comprises tetrafluoroethylene-perfluoroalkyl vinyl ether (PFA) and/or tetrafluoroethylene-hexafluoropropylene (FEP).

4. The fluororesin film according to claim 1, wherein the fluororesin film has a dielectric loss tangent at 10 GHz of less than 0.0015.

5. The fluororesin film according to claim 1, wherein the fluororesin film has a dielectric loss tangent at 10 GHz of less than 0.0010.

6. The fluororesin film according to claim 1, wherein the number of unstable functional groups is less than 10 per 1×10⁶ carbon atoms in a main chain of the fluororesin.

7. The fluororesin film according to claim 1, wherein the fluororesin film has adhesion strengths between metal foil having a surface roughness Rz of 1.5 μm or less and locations of center and 100 mm from respective left and right ends of the fluororesin film of 0.8 N/mm or more.

8. The fluororesin film according to claim 1, wherein the fluororesin film has adhesion strengths between a prepreg comprising an epoxy resin and/or polyphenylene ether and locations of center and 50 mm from respective left and right ends of the fluororesin film of 0.8 N/mm or more.

9. The fluororesin film according to claim 1, wherein one or both surfaces of the fluororesin film have an adhesion strength of more than 30 N/m when the surfaces of the film are mutually bonded at 200° C.

10. The fluororesin film according to claim 1, wherein the film is a long film.
